(19) United States
(12) Patent Application Publication
(10) Pub. No.: US 2022/0367641 A1
(43) Pub. Date: Nov. 17, 2022

(54) SILICON CARBIDE SEMICONDUCTOR DEVICE

(71) Applicant: FUJI ELECTRIC CO., LTD., Kawasaki-shi (JP)

(72) Inventors: Hiroyuki FUJISAWA, Matsumoto-city (JP); Akimasa KINOSHITA, Matsumoto-city (JP)

(73) Assignee: FUJI ELECTRIC CO., LTD., Kawasaki-shi (JP)

(21) Appl. No.: 17/706,801

(22) Filed: Mar. 29, 2022

(30) Foreign Application Priority Data
May 17, 2021 (JP) 2021-083311

(51) Int. Cl. H01L 29/16; H01L 29/423; H01L 29/739

(52) U.S. Cl. CPC H01L 29/1608; H01L 29/4236; H01L 29/7397

(57) ABSTRACT

A silicon carbide semiconductor device including a silicon carbide semiconductor substrate. The silicon carbide semiconductor substrate has an active region through which a main current flows, and a termination region surrounding a periphery of the active region in a top view of the silicon carbide semiconductor device. In the top view, the active region is of a rectangular shape, which has two first sides in a <11-20> direction and two second sides in a <1-100> direction. The two first sides are each of a first length, and the two second sides are each of a second length, the first length being longer than the second length.

### CROSS REFERENCE TO RELATED APPLICATIONS

This application is based upon and claims the benefit of priority of the prior Japanese Patent Application No. 2021-083311, filed on May 17, 2021, the entire contents of which are incorporated herein by reference.

### BACKGROUND OF THE INVENTION

### 1. Field of the Invention

Embodiments of the invention relate to a silicon carbide semiconductor device.

### 2. Description of the Related Art

Conventionally, silicon (Si) is used as a constituent material of power semiconductor devices for controlling high voltage and/or large current. There are several types of power semiconductor devices such as bipolar transistors, insulated gate bipolar transistors (IGBTs), and metal oxide semiconductor field effect transistors (MOSFETs) that have insulated gates (MOS gates) having a 3-layer structure including a metal, an oxide film, and a semiconductor; these devices are selectively used according to an intended purpose.

For example, bipolar transistors and IGBTs have high current density compared to MOSFETs and can be adapted for large current but cannot be switched at high speeds. In particular, the limit of switching frequency is about several kHz for bipolar transistors and about several tens of kHz for IGBTs. On the other hand, power MOSFETs have low current density compared to bipolar transistors and IGBTs and are difficult to adapt for large current but can be switched at high speeds up to about several MHz.

There is a strong demand in the market for large-current, high-speed power semiconductor devices and thus, IGBTs and power MOSFETs have been intensively developed and improved, and the performance of power devices has substantially reached the theoretical limit determined by the material. In terms of power semiconductor devices, semiconductor materials to replace silicon have been investigated and silicon carbide (SiC) has been focused on as a semiconductor material enabling fabrication (manufacture) of a next-generation power semiconductor device having low ON voltage, high-speed characteristics, and high-temperature characteristics.

SiC is a very stable material chemically, has a wide band gap of 3 eV, and may be used very stably as a semiconductor even at high temperatures. Further, SiC has a critical electric field strength that is at least ten times that of silicon. SiC has great potential to exceed the material limits of silicon and therefore, further growth is expected in power semiconductor applications, especially for MOSFETs. In particular, the on-resistance thereof is expected to be small. Vertical SiC-MOSFETs having lower on-resistance while maintaining high breakdown voltage characteristics can be expected.

In a conventional vertical MOSFET, an n⁻-type silicon carbide layer is deposited on a front surface of an n⁺-type silicon carbide substrate and a p-type base layer is selectively provided in the n⁻-type silicon carbide layer. Further, n⁺-type source regions and p⁺⁺-type contact regions are selectively provided in the p-type base layer, at the surface thereof.

A vertical MOSFET having such a structure has a built-in parasitic pn diode formed by the p-type base layer and the n⁻-type silicon carbide layer, as a body diode between a source and drain. The parasitic pn diode may be operated by an application of high potential to a source electrode. In this manner, in the MOSFET, unlike an IGBT, a parasitic pn diode is built-in and therefore, a free-wheeling diode (FWD) used in an inverter may be omitted, thereby contributing to cost reductions and size reductions. Hereinafter, a parasitic pn diode of the MOSFET is referred to as a body diode.

Further, a technique has been disclosed according to which on a silicon carbide semiconductor base, a mark indicating a crystal axis direction <11-20> of a silicon carbide substrate within an error range of 1 degree or, more preferably, within 0.5 degrees is provided and based on the mark, a trench pattern is formed, whereby the trench pattern may be formed with high precision parallel to the crystal axis direction <11-20> (for example, refer to Japanese Laid-Open Patent Publication No. 2018-37560).

### SUMMARY OF THE INVENTION

According to an embodiment of the invention, a silicon carbide semiconductor device includes a silicon carbide semiconductor substrate having an active region through which a main current flows, and a termination region surrounding a periphery of the active region in a top view of the silicon carbide semiconductor device. In the top view, the active region is of a rectangular shape, and has two first sides in a <11-20> direction and two second sides in a <1-100> direction. The two first sides are each of a first length, and the two second sides are each of a second length, the first length being longer than the second length.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view of a structure of a silicon carbide semiconductor device according to an embodiment.

FIG. 2 is a top view of the structure of the silicon carbide semiconductor device according to the embodiment.

FIG. 3 is a top view of the silicon carbide semiconductor device according to the embodiment in an initial state of stacking fault generation.

FIG. 4 is a top view depicting a state of the silicon carbide semiconductor device according to the embodiment after stacking fault growth.

FIG. 5 is a graph of rates of a stacking-fault total area relative to ratios of a length of an active region in a <11-20> direction/a length of the active region in a <1-100> direction.

FIG. 6 is a graph of rates of the stacking-fault total area relative to ratios of the length of the active region in the <11-20> direction/the length of the active region in the <1-100> direction.

FIG. 7 is a graph of rates of the stacking-fault total area relative to ratios of the length of the active region in the <11-20> direction/the length of the active region in the <1-100> direction.

FIG. 8 is a top view of a structure of a conventional silicon carbide semiconductor device.

FIG. 9 is a top view of the conventional silicon carbide semiconductor device in an initial state of stacking fault generation.

FIG. 10 is a top view depicting a state of the conventional silicon carbide semiconductor device after stacking fault growth.

### DETAILED DESCRIPTION OF THE INVENTION

First, problems associated with the conventional techniques are discussed. The crystal of the n⁺-type silicon carbide substrate may contain a defect. In this instance, when current flows through the body diode, holes are injected from the p-type base layer into the n⁻-type silicon carbide layer or the n⁺-type silicon carbide substrate, and electron and hole recombination occurs. Due to the recombination energy (3 eV) generated at this time corresponding to the band gap, basal plane dislocations that are one type of crystal defect present in the n⁺-type silicon carbide substrate may move and a stacking fault between two basal plane dislocations may extend in the <1-100> direction to a device element end.

When a stacking fault extends, the stacking fault does not easily pass current and therefore, on-voltage of the MOSFET and forward voltage of the body diode increase, and a bipolar degradation phenomenon occurs. When such operation continues, the stacking fault cumulatively extends and therefore, loss occurring in the inverter circuit increases over time and the amount of heat generated also increases, thereby causing device failure.

Embodiments of a silicon carbide semiconductor device according to the present invention will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. Cases where symbols such as n's and p's that include + or − are the same indicate that concentrations are close and therefore, the concentrations are not necessarily equal. In the description of the embodiments below and the accompanying drawings, main portions that are identical will be given the same reference numerals and will not be repeatedly described. Further, in the present description, when Miller indices are described, “−” means a bar added to an index immediately after the “−”, and a negative index is expressed by prefixing “−” to the index. Further, with consideration of variation in manufacturing, description indicating the same or equal may be within 5%.

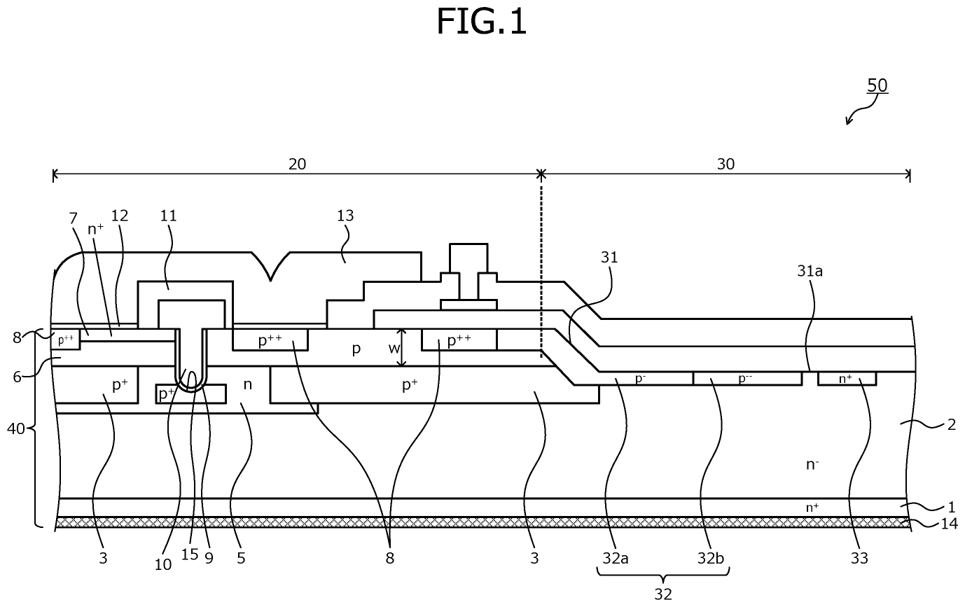

A semiconductor device according to the present invention contains a wide band gap semiconductor. In an embodiment, a silicon carbide semiconductor device fabricated (manufactured) using, for example, silicon carbide (SiC) as a wide band gap semiconductor is described taking a trench-type MOSFET 50 as an example. FIG. 1 is a cross-sectional view of a structure of the silicon carbide semiconductor device according to the embodiment.

As depicted in FIG. 1, the semiconductor device according to the embodiment has an active region 20 and an edge termination region 30 surrounding a periphery of the active region 20, on a semiconductor base (hereinafter, silicon carbide base (semiconductor substrate (semiconductor chip))) 40 containing silicon carbide. The active region 20 is a region through with current flows in an on-state. The edge termination region 30 is a region that mitigates electric field of a base-front-side of a drift region and sustains a breakdown voltage.

In the silicon carbide base 40, an n⁻-type semiconductor layer (n⁻-type silicon carbide layer) 2 containing silicon carbide and a p-type semiconductor layer (p-type silicon carbide layer) 6 containing silicon carbide are sequentially stacked on a front surface of an n⁺-type support substrate (n⁺-type silicon carbide substrate) 1 containing silicon carbide. The n⁺-type silicon carbide substrate 1 functions as a drain region. In the active region 20, p⁺-type base regions 3 and n-type regions 5 are selectively provided in the n⁻-type silicon carbide layer 2, at a first surface (base-front-side) thereof opposite to a second surface thereof facing the n⁺-type silicon carbide substrate 1.

Further, in the edge termination region 30, a JTE structure 32 is provided in which multiple p⁻-type low-concentration regions (here, two (2), a p⁻-type and a p⁻-type indicated by reference characters 32a and 32b, respectively, in a direction from the active region 20 to the edge termination region 30) are disposed adjacent to one another, in descending order of impurity concentration in the direction from the active region 20 to the edge termination region 30. Further, an n⁺-type semiconductor region 33 that functions as a channel stopper is provided between the JTE structure 32 and an end of the semiconductor chip (chip end). The JTE structure 32 and the n⁺-type semiconductor region 33 are provided at a bottom 31a of a drop 31 where a thickness of the n⁻-type silicon carbide layer 2 is relatively thinner due to the drop 31. Of the p⁺-type base regions 3, an outermost one closest to the chip end extends from the active region 20 to the edge termination region 30. A portion of the n⁻-type silicon carbide layer 2 other than the p⁺-type base regions 3 constitutes the drift region. The n-type regions 5 constitute a high-concentration n-type drift layer having an impurity concentration that is lower than that of the n⁺-type silicon carbide substrate 1 and higher than that of the n⁻-type silicon carbide layer 2.

On the first surface of the n⁻-type silicon carbide layer 2 opposite to the second surface thereof facing the n-type silicon carbide substrate 1, the p-type silicon carbide layer 6 is provided. The p-type silicon carbide layer 6 has an impurity concentration that is lower than an impurity concentration of the p⁺-type base regions 3. In the p-type silicon carbide layer 6, n⁺-type source regions 7 and p⁺⁺-type contact regions 8 are selectively provided.

A portion of the p-type silicon carbide layer 6 in the active region 20 is provided so as to cover the p⁺-type base regions 3 and the n-type regions 5. Further, the p-type silicon carbide layer 6 extends to the edge termination region 30 and in the edge termination region 30, is provided so as to cover the p⁺-type base regions 3 and the n⁻-type silicon carbide layer 2 up to the drop 31.

In a portion of the silicon carbide base 40 at the front side thereof in the active region 20, a trench structure is provided. In particular, trenches 15 penetrate through the n⁺-type source regions 7 and the p-type silicon carbide layer 6 from a first surface (front side of the silicon carbide base 40) of the p-type silicon carbide layer 6 opposite to a second surface thereof facing the n⁺-type silicon carbide substrate 1, and reach the n-type regions 5 and the p⁺-type base regions 3. Along inner walls of the trenches 15, a gate insulating film 9 is formed along bottoms and sidewalls of the trenches 15 and gate electrodes 10 are formed on the gate insulating film 9 in the trenches 15. The gate electrodes 10 are insulated from the n-type regions 5, the p⁺-type base regions 3, and the p-type silicon carbide layer 6 by the gate insulating film 9. A portion of each of the gate electrodes 10 may protrude toward a source electrode pad 13, from a top (side facing the source electrode pad 13) of each of the trenches 15.

An interlayer insulating film 11 is provided in an entire area of the front side of the silicon carbide base 40 so as to cover the gate electrodes 10 embedded in the trenches 15. Source electrodes 12 are in contact with the n⁺-type source regions 7 and the p⁺⁺-type contact regions 8, via contact holes in the interlayer insulating film 11. The source electrodes 12 are electrically insulated from the gate electrodes 10 by the interlayer insulating film 11. The source electrode pad 13 is provided on the source electrodes 12. On a back surface (back surface of the n⁺-type silicon carbide substrate 1) of the silicon carbide base 40, a drain electrode 14 is provided.

In FIG. 1, while only one trench MOS structure is depicted, MOS gate (insulated gate formed by a metal, an oxide film, and a semiconductor) structures of the trench gate structure may be further disposed in parallel.

Here, FIG. 8 is a top view of a structure of a conventional silicon carbide semiconductor device. As depicted in FIG. 8, in the conventional silicon carbide semiconductor device, an active region 120 has dimensions that are substantially equal in a vertical direction (<1-100> direction) and a horizontal (<11-20> direction) of the active region 120, i.e., a square shape. In this instance, assuming the active region 120 of a device element has a length X (cm) in the <11-20> direction and a length Y (cm) in the <1-100> direction and an edge termination region 130 has a length L (cm), then, an area S of the active region 120 is XY (cm²) and an area of the device element is (X+2L)(Y+2L) (cm²). A C-axis of the silicon carbide substrate has an off-angle in the <11-20> direction and to match the angles by which the left and right sidewalls of the trenches shift relative to the C-axis during formation of the trenches, the trenches are disposed in a stripe pattern so that a longitudinal dimension thereof is in the <11-20> direction.

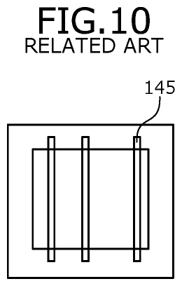

FIG. 9 is a top view of the conventional silicon carbide semiconductor device in an initial state of stacking fault generation. FIG. 9 depicts a state before conduction of a body diode of the conventional silicon carbide semiconductor device in which stacking faults 145 are present in the active region 120. FIG. 10 is a top view depicting a state of the conventional silicon carbide semiconductor device after stacking fault growth. Here, stacking fault growth is depicted in an instance in which, as a semiconductor substrate, a drift layer of about 30 μm is epitaxially grown on an n-type silicon carbide semiconductor substrate that has an off-angle of about 4 degrees. Due to conduction of the body diode, the stacking faults 145 extended beyond the active region 120, into the edge termination region 130, to positions therein corresponding to about 48% of the length L of the edge termination region 130. Beyond these positions in a direction toward the chip end, in the edge termination region 130, the spreading energy of the stacking faults 145 decreased and thus, the stacking faults 145 did not spread to the end of the edge termination region 130.

Assuming a length each of the stacking faults 145 in the <11-20> direction is “a” (cm), the area of each of the stacking faults 145 after spreading is a(Y+0.96L) (cm²). Assuming a number of occurrences of the stacking faults 145 per unit area is “D” (stacking fault/cm²), an occurrence count of the stacking faults 145 in a device element is D(X+2L)(Y+2L) (stacking faults) and when the area S of the active region 120 is fixed, Y=S/X and therefore, a total area of the stacking faults 145 after expansion is a(Y+0.96L)×DXY=a(S/X+0.96L)×DS=aDS²(1/X+0.96L/S) (cm²). Here, compared to the active region 120, the area of the edge termination region 130 is smaller and the occurrence count of the stacking faults 145 in the edge termination region 130 is lower, thus, the area for the edge termination region 130 is omitted. Accordingly, the longer is X, the smaller is the total area of the stacking faults 145. Hereinafter, a rated current is given preference, the area of the active region 120 is assumed to be fixed, and changes in cost due to changes in the area of the edge termination region 130 are not considered.

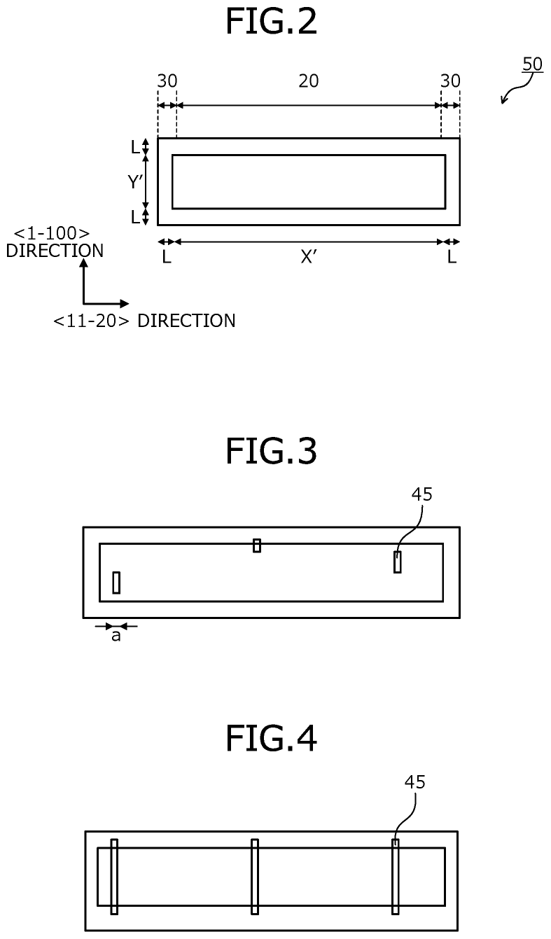

FIG. 2 is a top view of the structure of the silicon carbide semiconductor device according to the embodiment. As described above, a dimension in the <11-20> direction is longer than that in the <1-100> direction, whereby stacking fault occurrence area due to body diode conduction is reduced and the area of an effective region free of stacking faults may be increased.

Therefore, in the structure of the silicon carbide semiconductor device according to the embodiment, the active region 20 has a length X in the <11-20> direction longer than a length Y′ thereof in the <1-100> direction (X′>Y′), i.e., a rectangular shape. The n⁺-type silicon carbide substrate has an off-angle of about four degrees and while the off-angle is provided in the <11-20> direction, herein, the substrate off-angle is disregarded. In this instance, assuming the length of the edge termination region 30 is “L”, then an area S′ of the active region 20 is X′Y′ (cm²) and the area of the device element is (X′+2L)(Y′+2L) (cm²).

FIG. 3 is a top view of the silicon carbide semiconductor device according to the embodiment in an initial state of stacking fault generation. FIG. 3 depicts a state before condition of a body diode of the silicon carbide semiconductor device according to the embodiment in which stacking faults 45 are present in the active region 20. FIG. 4 is a top view depicting a state of the silicon carbide semiconductor device according to the embodiment after stacking fault growth. Here as well, stacking fault growth is depicted in an instance in which, as a semiconductor substrate, a drift layer of 30 μm is epitaxially grown on an n-type silicon carbide semiconductor substrate having an off-angle of about four degrees. Due to conduction of the body diode, the stacking faults 45 extend beyond the active region 20, into the edge termination region 30, to positions therein corresponding to about 48% of the length L of the edge termination region 30.

Assuming a length of each of the stacking faults 45 in the <11-20> direction is “a” (cm), the area of each of the stacking faults 45 after spreading is a(Y′+0.96L) (cm²). Assuming the number of occurrences of the stacking faults 45 per unit area is “D” (stacking fault/cm²), the occurrence count of the stacking faults 45 in a device element is D(X′+2L)(Y′+2L) (stacking faults) and when the area S of the active region 20 is fixed, Y′=S/X′ and therefore, the total area of the stacking faults 45 after expansion is a(Y′+0.96L)×DX′Y′=a(S/X′+0.96L)×DS=aDS²(1/X′+0.96L/S) (cm²). For a same reason as that in the conventional case, the area for the edge termination region 30 is disregarded. Accordingly, the longer is X′, the smaller is the total area of the stacking faults 45.

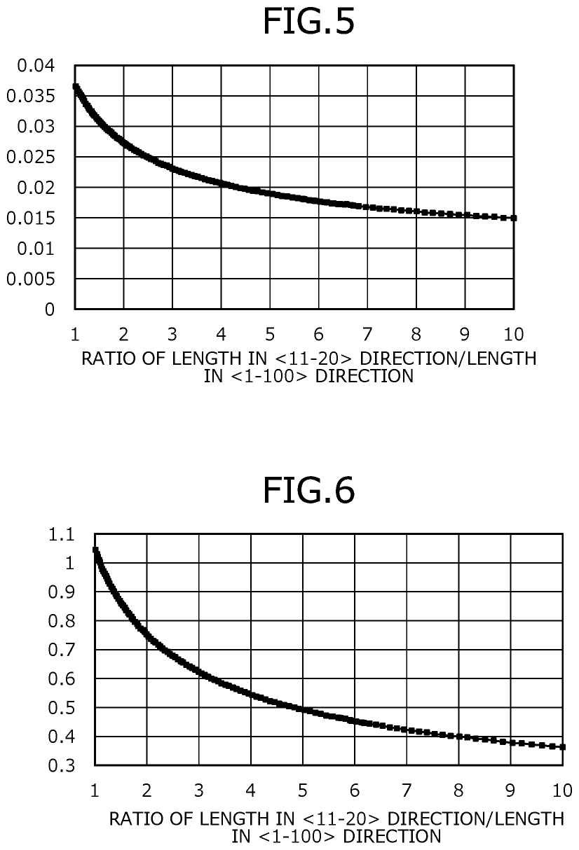

FIGS. 5, 6, and 7 are graphs of rates of stacking-fault total area relative to ratios of the length of the active region in the <11-20> direction/the length of the active region in the <1-100> direction. Here, the total area of the stacking faults 45 after expansion is aDS²(1/X′+0.96L/S) (cm²), where “aD” is determined by the material and thickness regardless of the shape of the active region 20 and therefore, standardized by “aD”. Therefore, in FIGS. 5 to 7, horizontal axes indicate the ratio of the length of the active region in the <11-20> direction to the length of the active region in the <1-100> direction (length in the <11-20> direction/length in the <1-100> direction) and vertical axes indicate a standardized value y=S²(1/X′+0.96L/S).

FIG. 5 shows results for an instance in which L=0.05 cm and S=0.1 cm² and as depicted in FIG. 5, when the ratio of the length of the active region in the <11-20> direction to the length of the active region in the <1-100> direction is:

1.14 times, then y=0.944

1.28 times, then y=0.897

1.70 times, then y=0.796

2.35 times, then y=0.697

3.44 times, then y=0.599

5.58 times, then y=0.499

FIG. 6 shows results for an instance in which L=0.05 cm and S=1 cm² and as depicted in FIG. 6, when the ratio of the length of the active region in the <11-20> direction to the length of the active region in the <1-100> direction is:

1.11 times, then y=0.948

1.26 times, then y=0.895

1.60 times, then y=0.798

2.17 times, then y=0.693

2.99 times, then y=0.597

4.47 times, then y=0.496

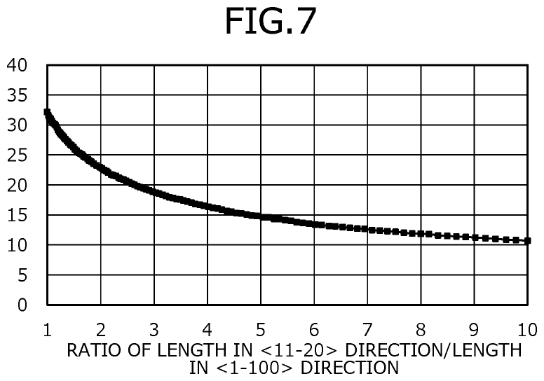

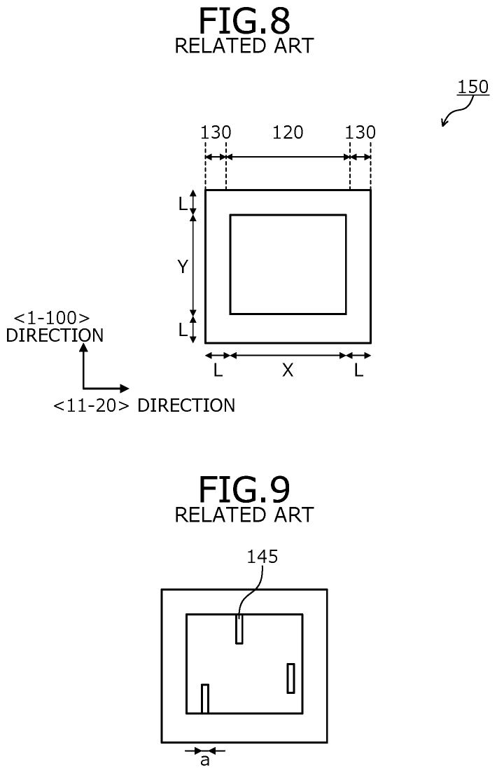

FIG. 7 shows results for an instance in which L=0.05 cm and S=10 cm² and as depicted in FIG. 7, when the ratio of the length of the active region in the <11-20> direction to the length of the active region in the <1-100> direction is:

1.11 times, then y=0.946

1.26 times, then y=0.892

1.60 times, then y=0.792

2.08 times, then y=0.697

2.87 times, then y=0.595

4.12 times, then y=0.499

As mentioned above, it is found that the greater is the ratio of the length of the active region in the <11-20> direction to the length of the active region in the <1-100> direction, the smaller is the rate of the stacking-fault total area. In the embodiment, preferably, the ratio of the length of the active region in the <11-20> direction to the length of the active region in the <1-100> direction may be in a range from 1.5 times to 4 times or more preferably, may be in a range from 2 times to 3 times.

For example, by setting the ratio of the length of the active region in the <11-20> direction to the length of the active region in the <1-100> direction to at least 1.5 times, the rate of the stacking-fault total area may be set to about 0.8 (20% lower than conventionally) and by setting the ratio to at least 2 times, the rate of the stacking-fault total area may be set to about 0.7 (30% lower than conventionally). As a result, even in an instance in which stacking faults have expanded, the ratio of the stacking-fault total area to the active region is reduced and therefore, bipolar degradation phenomena such as on-voltage increases may be suppressed.

Further, by increasing the ratio of the length of the active region in the <11-20> direction to the length of the active region in the <1-100> direction, a dimension in a lateral direction increases and a region for connecting a wire to the source electrode pad decreases. Further, when the dimension in the lateral direction increases, at an end portion, a distance from a gate electrode pad increases and unbalance increases when off and on and therefore, the gate electrode pad is provided in plural. Therefore, preferably, the ratio of the length of the active region in the <11-20> direction to the length of the active region in the <1-100> direction may be at most 4 times or more preferably, may be at most 3 times.

A method of manufacturing the silicon carbide semiconductor device according to the embodiment may be created by a method such as that described below. Here, an instance in which a MOSFET having a breakdown voltage of 1200V is fabricated is described as an example. First, the n⁺-type silicon carbide substrate (semiconductor wafer) 1 containing single crystal silicon carbide and doped with an n-type impurity (dopant) such as nitrogen (N) to have an impurity concentration of, for example, 2.0×10¹⁹/cm³ is prepared. The front surface of the n⁺-type silicon carbide substrate 1, for example, may be a (0001) plane having an off-angle of about four degrees in the <11-20> direction. Next, the n-type silicon carbide layer 2 doped with an n-type impurity such as nitrogen to have an impurity concentration of, for example, 1.0×10¹⁶/cm³ is epitaxially grown on the front surface of the n⁺-type silicon carbide substrate 1 and has a thickness of, for example, 10 μm.

Next, by photolithography and ion implantation, the n-type regions 5 are selectively formed in a surface layer of the n⁻-type silicon carbide layer 2. In this ion implantation, an n-type impurity (dopant) such as nitrogen may be implanted so as to have a concentration of, for example, 1×10¹⁷/cm³.

Next, by photolithography and ion implantation, the p⁺-type base regions 3 are selectively provided in a surface layer of the n⁻-type silicon carbide layer 2. Of the p⁺-type base regions 3, an outermost one closest to the chip end is formed so as to extend into the edge termination region 30. In this ion implantation, a p-type impurity (dopant) such as aluminum (Al) may be ion implanted so that an impurity concentration of the p⁺-type base regions 3 is, for example, 5.0×10¹⁸/cm³.

Next, the p-type silicon carbide layer 6 doped with a p-type impurity such as aluminum so as to have an impurity concentration of, for example, 2.0×10¹⁷/cm³ is epitaxially grown on the surface of the n⁻-type silicon carbide layer 2 and has a thickness of, for example, 1.3 μm.

By the processes up to here, the silicon carbide base 40 in which the n⁻-type silicon carbide layer 2 and the p-type silicon carbide layer 6 are sequentially stacked on the front surface of the n⁺-type silicon carbide substrate 1 is fabricated. Next, a process including formation of an ion implantation mask by photolithography and etching, ion implantation using this ion implantation mask, and removal of the ion implantation mask performed as one set is repeatedly performed under different conditions, whereby the n⁺-type source regions 7 and the p⁺⁺-type contact regions 8 are formed in a surface layer of the p-type silicon carbide layer 6.

Next, by photolithography and etching, the drop 31 is formed at the surface of the p-type silicon carbide layer 6 in the edge termination region 30, so as to have a depth of, for example, 1.5 μm from the surface of the p-type silicon carbide layer 6, thereby partially removing the p-type silicon carbide layer 6 and the n⁻-type silicon carbide layer 2 and exposing the n⁻-type silicon carbide layer 2. Next, by photolithography and ion implantation, the JTE structure 32 is selectively removed. Next, by photolithography and ion implantation, the n⁺-type semiconductor regions 33 are selectively formed.

Next, a heat treatment (annealing) is performed, thereby activating, for example, the p⁺-type base regions 3, the n⁺-type source regions 7, the p⁺⁺-type contact regions 8, the JTE structure 32, and the n⁺-type semiconductor region 33. A temperature of the heat treatment may be, for example, about 1700 degrees C. A period of the heat treatment may be, for example, about 2 minutes. As described above, all ion-implanted regions may be activated collectively by a single session of the heat treatment, or the heat treatment may be performed each time ion implantation is performed.

Next, from the surface of the p-type silicon carbide layer 6 (i.e., surfaces of the n⁺-type source regions 7 and the p⁺⁺-type contact regions 8), by photolithography and etching, the trenches 15 that penetrate through the n⁺-type source regions 7 and the p-type silicon carbide layer 6 and reach the n-type regions 5 are formed. Bottoms of the trenches 15 reach the p⁺-type base regions 3.

Next, along surfaces of the n⁺-type source regions 7 and the p⁺⁺-type contact regions 8 as well as the bottoms and sidewalls of the trenches 15, the gate insulating film 9 is formed. The gate insulating film 9 may be formed by thermal oxidation of a temperature of about 1000 degrees C. under an oxygen atmosphere. Further, the gate insulating film 9 may be formed by a deposition method by a chemical reaction such as that for a high temperature oxide (HTO).

Next, on the gate insulating film 9, a polycrystalline silicon layer doped with, for example, phosphorus (P) atoms is formed. The polycrystalline silicon layer is formed so as to be embedded in the trenches 15. The polycrystalline silicon layer is patterned and left in the trenches 15, whereby the gate electrodes 10 are formed. A portion of each of the gate electrodes 10 may protrude toward the source electrode pad 13, from a top (side facing the source electrode pad 13) of each of the trenches 15.

Next, for example, phosphate glass (PSG) is deposited so as to cover the gate insulating film 9 and the gate electrodes 10 and have a thickness of about 1 μm, whereby the interlayer insulating film 11 is formed. The interlayer insulating film 11 and the gate insulating film 9 are patterned and selectively removed, whereby contact holes are formed, thereby exposing the n⁺-type source regions 7 and the p⁺⁺-type contact regions 8. Thereafter, a heat treatment (reflow) is performed, whereby the interlayer insulating film 11 is planarized.

Subsequently, in the contact holes and on the interlayer insulating film 11, a conductive film constituting the source electrodes 12 is formed. The conductive film is selectively removed, for example, thereby leaving the source electrodes 12 only in the contact holes.

Subsequently, on the back surface of the silicon carbide base 40 (the back surface of the n⁺-type silicon carbide substrate 1), the drain electrode 14 is formed constituted by, for example, a nickel (Ni) film. Thereafter, a heat treatment of a temperature of, for example, about 970 degrees C. is performed, whereby the n⁺-type silicon carbide substrate 1 and the drain electrode 14 form an ohmic bond with each other.

Next, for example, by a sputtering method, for example, an aluminum film is provided so as to cover the source electrodes 12 and the interlayer insulating film 11 and have a thickness of, for example, about 5 μm. Thereafter, the aluminum film is selectively removed and left so as to cover the active region 20, whereby the source electrode pad 13 is formed.

Next, on the surface of the drain electrode 14, for example, titanium (Ti), nickel (Ni), and gold (Au) are sequentially stacked, whereby a drain electrode pad is formed. In this manner, the semiconductor device depicted in FIG. 1 is completed.

As described above, according to the embodiment, the length of the active region in the <11-20> direction is made longer than the length of the active region in the <1-100> direction. As a result, when a body diode conducts even in an instance in which a stacking fault has expanded, the ratio of the stacking-fault total area to the active region may be less than that conventionally. Therefore, even in instances in which a stacking fault has expanded, bipolar degradation phenomena such as on-voltage increases may be suppressed.

In the foregoing, the present invention may be variously modified within a range not departing from the spirit of the invention and in the embodiments described above, for example, dimensions, impurity concentrations, etc. of parts are variously set according to necessary specifications. Further, in the present invention, while a first conductivity type is assumed to be a p-type and a second conductivity type is assumed to be an n-type in the embodiments, the present invention is similarly implemented when the first conductivity type is an n-type and the second conductivity type is a p-type.

According to the invention described above, the length of the active region in the <11-20> direction is made longer than the length of the active region in the <1-100> direction. As a result, when the body diode conducts even in an instance in which a stacking fault has expanded, the ratio of the stacking-fault total area to the active region may be reduced compared to that conventionally. Therefore, even in an instance in which a stacking fault has expanded, bipolar degradation phenomena such as on-voltage increases may be suppressed.

The silicon carbide semiconductor device according to the present invention achieves an effect in that even in an instance in which a stacking fault has expanded, bipolar degradation phenomena may be suppressed.

As described above, the silicon carbide semiconductor device according to the present invention is useful for power semiconductor devices used in power converting equipment of inverters, etc., power source devices such as those of various types of industrial machines, inverters of automobiles, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide semiconductor device, comprising:
a silicon carbide semiconductor substrate having
an active region through which a main current flows, and
a termination region surrounding a periphery of the active region in a top view of the silicon carbide semiconductor device, wherein, in the top view,
the active region is of a rectangular shape, and has two first sides in a <11-20> direction and two second sides in a <1-100> direction, and
the two first sides are each of a first length, and the two second sides are each of a second length, the first length being longer than the second length.

2. The silicon carbide semiconductor device according to claim 1, wherein
the silicon carbide semiconductor substrate has an off-angle provided in the <11-20> direction.

3. The silicon carbide semiconductor device according to claim 1, wherein
a ratio of the first length to the second length is in a range from 1.5 to 4.

4. The silicon carbide semiconductor device according to claim 1, wherein
a ratio of the first length to the second length is in a range from 2 to 3.

5. The silicon carbide semiconductor device according to claim 1, further comprising, in the active region, a metal-oxide film-semiconductor (MOS) type semiconductor device having a trench gate.

6. The silicon carbide semiconductor device according to claim 5, wherein
the trench gate includes a trench, of which a longitudinal dimension is in the <11-20> direction.

7. The silicon carbide semiconductor device according to claim 6, further comprising a plurality of gate electrode pads in the <11-20> direction.
